(19) United States
(12) Patent Application Publication
(10) Pub. No.: US 2012/0199956 A1
(43) Pub. Date: Aug. 9, 2012

(54) METHOD FOR RECYCLING A SOURCE SUBSTRATE

(76) Inventors: Monique Lecomte, Biviers (FR); Pascal Guenard, Froges (FR); Sophie Rigal, Saint Martin D'heres (FR); David Sotta, Grenoble (FR); Fabienne Janin, Ste Helene Du Lac (FR); Christelle Veytizou, Bernin (FR)

(21) Appl. No.: 13/368,028

(22) Filed: Feb. 7, 2012

(30) Foreign Application Priority Data
Feb. 8, 2011 (FR) FR 1150999

(51) Int. Cl. H01L 29/02; H01L 21/762; H01L 21/02

(52) U.S. Cl. 257/629; 438/471; 438/458; 257/E21.002; 257/E21.568; 257/E29.002

(57) ABSTRACT

The present invention relates to process for recycling a source substrate that has a surface region and regions in relief on the surface region, with the regions in relief corresponding to residual regions of a layer of the source substrate that were not being separated from the rest of the source substrate during a prior removal step. The process includes selective electromagnetic irradiation of the source substrate at a wavelength such that the damaged material of the surface region absorbs the electromagnetic irradiation. The present invention also relates to a recycled source substrate and to a process for transferring a layer from a source substrate recycled for this purpose.

### TECHNICAL FIELD

The field of the invention is that of semiconductor substrates used in the electronics, optics or optoelectronics industry.

The invention more precisely relates to the recycling of semiconductor substrates from which a thin layer of material has been removed.

### BACKGROUND ART

Silicon-on-insulator (SOI) structures are structures consisting of a multilayer comprising a very thin layer of silicon on an insulator layer, itself generally on a substrate. These structures are increasingly used in the electronics industry because of their superior performance.

This type of structure is generally produced using Smart-Cut™ technology and FIGS. 1a-c show the main steps for producing an SOI wafer.

FIG. 1a shows a source or “donor” substrate 1 one side of which is subjected to implantation via bombardment with ionic species 10 (for example H⁺ ions) so as to create, at a certain depth in the substrate, a weakened zone 2. As illustrated in FIG. 1b, the side of the source substrate 1 which was subjected to the implantation is brought into intimate contact with a support or “receiver” substrate 3 so as to produce a bond via molecular adhesion. This support substrate 3 may have an insulating layer on its surface, this insulating layer being obtained for example by oxidation of the surface. Next, as shown in FIG. 1c, the source substrate is cleaved along a median plane of the weakened zone 2 so as to transfer to the support substrate 3 the part of the source substrate 1 located between its external side and the weakened zone 2, the transferred part forming thin useful layer 4.

As illustrated in FIG. 1c, an “exclusion zone” which corresponds to a non-transferred part of the thin layer 4 is formed on the periphery of the support substrate 1.

This is because, as illustrated very schematically in FIG. 1b, the source substrate 1 and the support substrate 3 respectively comprise on their peripheries a bevel or “edge rounding” 1a and 3a the role of which is to make handling the substrates easier and to prevent edge flaking which could occur if these edges were sharp, such flakes being a source of particulate contamination of the wafer surfaces.

The presence of such a bevel, however, prevents good contact between the support substrate 3 and the source substrate 1 at their periphery. The bonding force obtained at the periphery of the assembly is therefore insufficient to retain, over its entire diameter, the part of the source substrate 1 to be transferred to the support substrate 3. The layer 4 to be transferred has a small thickness, limited to several hundred nanometers, because it is formed by implantation. This small thickness weakens it and it breaks at the bevel during detachment. The detached layer 4 of source substrate 1 is therefore not transferred at the periphery of the support and there is therefore a residual part that remains and that creates a zone 5 that is in relief relative to the detachment surface, this peripheral zone 5 taking the form of a “ring”.

It is necessary to remove this ring if it is desired to recycle the source substrate 1 stripped of the layer 4, this being called the “negative”, in order to reuse it as a “positive” donor in order to transfer a new thin layer. Furthermore, zones of material are sometimes not transferred and may remain on the surface of the negative. The expression “regions in relief” will be understood in the remainder of the description of the invention to mean all of the zones in relief relative to the detachment surface in general, the invention in no way being limited to removal of the ring alone, even if it represents most of the regions in relief, but also relating to removal of non-transferred zones present on the surface of the negative.

Techniques have been provided to remove the regions in relief 5 and allow the source substrate 1 to be recycled. Document EP 1 427 002 in particular proposes a chemical-mechanical polishing of the surface of the source substrate 1, and use of a water, air or fluid jet, a laser beam, shock waves or ion bombardment locally targeted at the regions in relief 5, in particular targeted at the weakened zone 2.

None of these methods are completely satisfactory, however, and the materials of certain source substrates (SiC, GaN, AlN, AlGaN, etc.) are relatively hard and difficult to polish. The chemical-mechanical polishing is therefore a long and costly procedure. Energy-based techniques, such as those using a laser beam, are not selective to the regions of relief and may damage the rest of the source substrate unless they are controlled very precisely.

In addition, substrates have increasingly large diameters (six inches for example or more), thereby amplifying the aforementioned difficulties. In particular there is a risk that defects, for example micro-scratches, will form if excessive polishing or non-selective energy techniques are used. Thus, there is a need for improved processes for removing these regions in relief, especially from larger diameter substrates. The present invention now provides improved processes that meet this need.

### SUMMARY OF THE INVENTION

The invention relates to improvements in a process for recycling a source substrate that has been used to supply a layer of surface material by a layer detachment and transfer process and which contains regions in relief relative to the detachment surface which regions include non-transferred zones of damaged material present on the surface of the source substrate. The improvement comprises applying selective electromagnetic irradiation to the source substrate at a wavelength such that the damaged material of the surface regions in relief absorbs the electromagnetic irradiation to facilitate selective removal of such regions to thus facilitate recycling of the source substrate. Advantageously, the regions in relief are then removed from the surface of the support substrate, optionally with polishing, so that the source substrate can be recycled in a form that is ready for transfer of a further layer from the surface of the recycled source substrate.

The invention also relates to a recycled source substrate prepared by the process disclosed herein so that it is in a condition ready to provide an additional layer of material for transfer to another support substrate.

### BRIEF DESCRIPTION OF THE DRAWINGS

Other features and advantages of the present invention will become clear on reading the description which follows of a preferred embodiment. This description will be given with reference to the appended drawings in which:

FIGS. 1a-c, described above, are diagrams illustrating the main steps of a conventional Smart-Cut™ process and explaining how a ring forms;

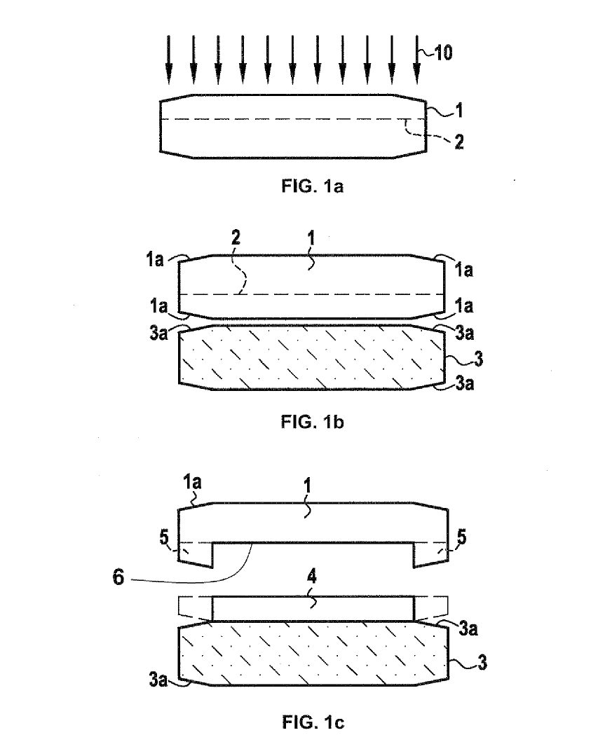

FIG. 2 is a diagram showing the steps of an embodiment of a recycling process according to the invention associated with a transferring process; and

FIG. 3 is a diagram showing the residual region and regions in relief in detail.

### DETAILED DESCRIPTION OF THE INVENTION

The present invention aims to make removal of the ring of residual material on a donor substrate easier and therefore to make recycling this substrate easier, by reducing the duration, the quality and the cost of the recycling operations.

For this purpose, the present invention relates to, according to a first aspect, a process for recycling a source substrate comprising a surface region and regions in relief on the surface region. These regions in relief correspond to residual regions of a layer of the source substrate, wherein the residual regions were not separated from the rest of the source substrate during a prior removal step implementing a separation at a weakened zone formed by damaged material of the source substrate. The surface region corresponds to part of the weakened zone not separated from the rest of the source substrate during the prior removal step. The process comprises applying selective electromagnetic irradiation to the source substrate at a wavelength such that the damaged material of the surface region absorbs the electromagnetic irradiation to facilitate recycling of the source substrate.

It is thus possible to carry out electromagnetic irradiation at a defined wavelength over the entire area of the source substrate to be recycled, only the damaged material located at the base of the ring or the non-transferred regions in relief will absorb the radiation and then will be selectively removed. The power of the radiation is thus chosen so that the heating of the material to be removed does not damage neighbouring zones, resulting in the substrate being in an optimal state at the end of the recycling operation.

According to other advantageous and non-limiting features:

the regions in relief correspond to a ring of material from the layer of the source substrate and/or to non-transferred zones of material from the layer of the source substrate distributed randomly on the surface region;

the selective electromagnetic irradiation is carried out over the entire area of the source substrate;

the selective electromagnetic irradiation is controlled by an optical device that detects the regions in relief so that the irradiation is carried out locally on the regions in relief;

the optical device detects the regions in relief via the difference in optical contrast between the damaged material of the weakened zone and the undamaged material of the source substrate;

the source substrate consists of a bulk material chosen from at least one of the following materials: SiC or a binary, ternary or quaternary III-N material; or consists of a composite structure of the GaNOS, InGaNOS, SiCOI or SiCopSiC type;

the weakened zone is generated by implanting ionic or atomic species into the source substrate;

the surface region of the source substrate can be subjected to chemical-mechanical polishing following the selective electromagnetic irradiation;

the chemical-mechanical polishing uses a colloidal acid solution enriched with an oxidizing agent and/or an additive of abrasive particles, in particular diamond particles;

the selective electromagnetic irradiation of the source substrate is carried out by a laser or other light energy generating means;

when the material of the source substrate is GaN, the laser emits at a wavelength longer than or equal to 370 nm;

when the material of the source substrate is SiC, the laser emits at a wavelength longer than or equal to 415 nm;

the preferred laser is a pulsed-mode yttrium-aluminium-garnet laser;

the laser has a power density of about 0.1 to 2 J/cm²;

the process comprises epitaxial growth of at least one layer of material on one surface of the source substrate; and

the epitaxial growth of material is carried out on the surface exposed following the selective electromagnetic irradiation.

According to a second aspect, the invention relates to a source substrate recycled by a process according the first aspect of the invention so as to be reused.

The invention lastly relates, according to a third aspect, to a process for transferring a layer from a source substrate, recycled according to the second aspect of the invention, to a support substrate which comprises:

generating a weakened zone in the recycled source substrate at a depth bounding the thickness of the layer;

bringing the recycled source substrate and a support substrate into contact; and

fracturing heat treatment.

For example, a source substrate obtained according to the invention can then be recycled after the regions in relief are removed, optionally with polishing of the surface. The source substrate can then provide an additional layer of material. Removing a layer from the surface of the recycled source substrate can be accomplished by generating a weakened zone in the recycled source substrate at a depth bounding the thickness of the layer; and applying a fracturing treatment to remove the layer. Alternatively, the process further comprises transferring a layer. This is done by bonding the recycled source substrate to a support substrate prior to applying the fracturing treatment so that the fracturing treatment transfers the layer to the support substrate. After either removal or transfer, the source substrate can again be treated by irradiation as disclosed herein and then again recycled.

The invention is based on the fact that weakening the material of a source substrate 1 damages its crystal structure to the extent that its optical transmission spectrum is singularly modified. The bands of the spectrum in which the material is transparent to, or on the contrary absorbs, radiation are effectively moved because of the damage to the crystal structure. The invention provides, in a general way, for use of electromagnetic irradiation of the substrate to be recycled at a wavelength at which the damaged material absorbs while the material, the crystal structure of which is not damaged, or only slightly damaged, does not absorb or absorbs much less.

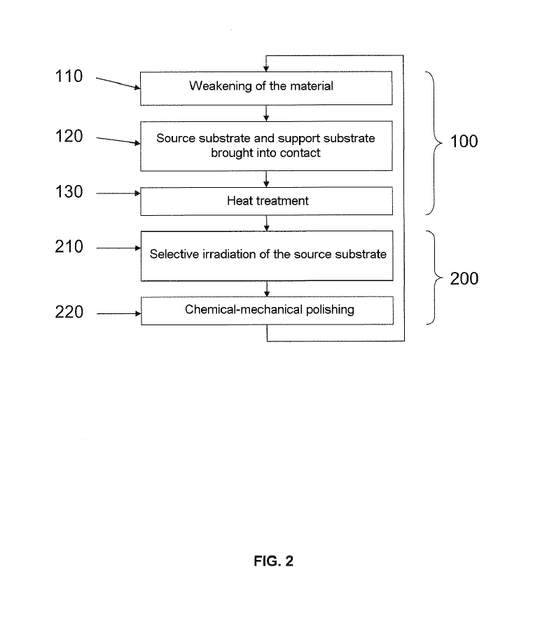

As explained above, and as shown in FIG. 2, the process 200 for recycling a source substrate 1 according to the invention follows a prior process 100 for separating a layer 4 from a source substrate 1, this process 100 advantageously comprising the transfer of a layer 4 from the source substrate 1 to a support substrate 3.

The invention is however not limited to such a transfer, but targets more generally any separation of a layer 4 following the weakening of the source substrate 1, especially by implantation of ionic species. Moreover, since the support substrate 3 acts to provide the layer 4 with stiffness, the substrate may not only be bonded to the layer 4 before separation but may also be deposited onto the layer 4 by any deposition method, typically epitaxial growth. Furthermore, the layer 4 may be thick and rigid enough to be self-supporting (it is possible to handle it without it rolling up or without it breaking) or at least it may be used without an external source of rigidity being needed. Thus, in the absence of a supporting substrate 3, removal or detachment of the layer 4 is spoken of, and not transfer.

Following this prior process 100, the negative, i.e. the source substrate 1 stripped of the transferred layer 4, comprises regions 5 in relief relative to a surface region 6, these regions 5 in relief being residual regions of the layer 4, and therefore consist of left-over material from the layer 4.

Advantageously, the source substrate 1 consists of a material chosen from at least one of the following materials: SiC or a binary, ternary or quaternary III-N material such as GaN, AlN, AlGaN or InGaN. The source substrate 1 may also consist of a composite structure comprising a mechanical support to which a layer of material from the above list has been bonded. Typically the composite structure may be SiCopSiC (a layer of SiC bonded to a polycrystalline SiC substrate), or GaNOS (a layer of GaN bonded to a sapphire substrate). The source substrate 1 may also be a composite structure on which a layer has been deposited; this is the case for InGaNOS in which a layer of InGaN is deposited by epitaxy on a GaNOS structure. The support substrate 3 consists of a material chosen from at least one of the following materials: AlN, GaN, SiC, sapphire, a ceramic and/or a metal alloy. The invention is however not limited to any particular combination of material.

### Steps of the Transfer and Recycling Processes

The prior separating process 100 advantageously comprises, in the case of a transferring process, a cleavage or fracture of the source substrate 1 at a weakened zone 2 formed of a damaged material separating the layer 4 from the rest of the source substrate 1.

In this case, the transferring process 100 comprises, in an implementation that is particularly advantageous, three steps. First the weakened zone 2 is created by a step 110 of weakening the material. Advantageously, this is achieved by implantation of ionic or atomic species. The surface of the substrate 1 is bombarded by a beam of such species with a defined energy and dose. These species penetrate into the material to a preset depth which defines the thickness of the layer 4 to be removed or transferred.

Once the weakened zone 2 has been generated, the source substrate 1 and the support substrate 3 are brought into contact during a second step 120 so as to bond by molecular adhesion. Prior to this step, the source substrate 1 and/or the support substrate 3 may optionally be oxidized. Depending on the nature of the material, and especially in the case of III-N materials, sapphire and SiC, a layer of silicon dioxide (SiO₂) or of silicon nitride (SiₓN_{y}) may be deposited, this layer increasing the bonding energy between the surfaces which have been brought into contact.

A fracturing treatment 130 completes the transfer process. This can be achieved by mechanical means but is more conveniently conducted by applying a fracturing heat treatment. A temperature increase caused by heating of the substrates, strengthens the bond between the two substrates 1 and 3 and also causes a fracture in the implanted region (weakened zone 2). The layer 4 is detached from the substrate 1, except at the periphery and on other regions randomly distributed over the surface of the substrate, these all forming regions in relief 5.

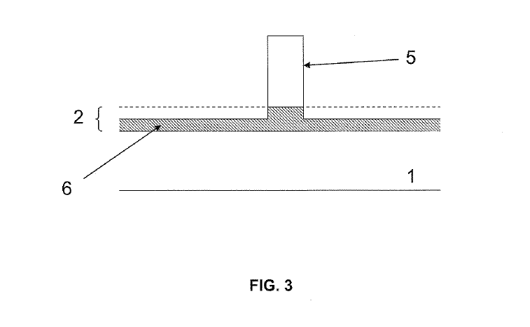

It is important to note that the weakened zone 2 is in fact a region with a volume, as may be seen in the schematic representation of FIG. 3. The weakened zone 2 in fact has a thickness that corresponds to the deepest and shallowest penetration of the ionic species during the bombardment. This is because, although implanted into the source substrate 1 with a high precision, the ionic species are in fact distributed over a narrow band with a peak at its median plane, roughly with a Gaussian distribution, meaning that the weakened zone 2 is a volume of damaged material and not a plane, the damage being greatest in the median plane.

The fracture plane along which the layer 4 is detached from the substrate 1 is therefore located at this median plane, in the thickness of the weakened zone 2: part of the weakened zone 2 is therefore found on each of the surfaces of the layer 4 and of the substrate 1.

It will be noted that a “surface region” is described herein. This surface region 6 indicates that part of the weakened zone 2 that is not separated from the rest of the source substrate 1, this part consisting of a layer of damaged material of variable thickness located over the entire area of the source substrate 1, as may be seen in FIG. 3. Thus, since they are still attached to the negative of the substrate 1, the regions in relief 5 have at their base the whole thickness of the weakened zone 2.

Absorption of the electromagnetic radiation by the damaged material that forms the remnants of the weakened zone 2 makes it possible to remove the surface region 6, and therefore to detach the residual region 5 from the source substrate 1.

Implantation of ionic species into a material effectively damages the crystal structure of the material by creating various defects, until the material becomes amorphous, thereby modifying the optical absorption spectrum of the material. The recycling process 200 according to the invention also comprises at least one substep 210 of electromagnetic irradiation of the source substrate 1.

By carrying out selective electromagnetic irradiation at a defined wavelength, only the damaged material of the weakened zone 2 will absorb the energy of the radiation and be selectively transformed, the transformation advantageously being destruction due to substantial heating. The rest of the material is transparent to the radiation and will quite simply be passed through without modification. As explained above, the residual parts of the weakened zone 2 form the surface region 6 and are located in particular interposed between the regions 5 in relief and the rest of the source substrate 1.

The power of the radiation may be chosen so that the heating of the material to be removed does not damage the neighbouring zones. It is furthermore possible to use any sort of ionic species that allow the implanted material to be fractured, such as commonly used hydrogen and/or helium.

Advantageously, the selective electromagnetic irradiation is carried out over the entire area of the negative to be recycled, whatever the inclination and position of the source, which is preferably a laser. The irradiation may also be swept over the edge face of the substrate, this being useful in the case where a layer is removed by implantation from an ingot. There is no longer any need to target a beam precisely at the interface between the regions 5 in relief and the surface region 6, as was sometimes the case in certain process of the prior art. To do this, the laser is moved so as to sweep at least once over the whole area of the source substrate 1. As the undamaged material is transparent to the irradiation at the wavelength chosen, it is possible to irradiate portions of the surface of the source substrate 1 several times.

Alternatively, the selective electromagnetic irradiation is carried out locally in the regions in relief 5 under the control of an optical device that detects the regions in relief 5. This is because, since the damaged material of the weakened zone 2 and the undamaged material of the source substrate 1 have different optical absorptions, it is possible, via the difference in contrast, to see the zones of the area of the source substrate 1 in which the thickness of damaged material is larger than elsewhere. As may be seen in FIG. 3, these zones are located at the base of the regions in relief 5. Thus the optical device, which may be a simple video camera, advantageously detects the regions in relief 5 by virtue of this principle.

By coupling such an optical device to the laser, it is possible to control the latter so that it emits selective electromagnetic irradiation only when it is aimed at zones 5 in relief. This embodiment enables, at low cost, time and energy savings since the laser is activated for much less time.

For III-N materials and in particular for GaN, which absorbs, when it is damaged, from a wavelength of 370 nm, or for SiC which absorbs, when it is damaged, from a wavelength of 415 nm, pulsed-mode doubled YAG (yttrium-aluminium-garnet) lasers configured to emit at a wavelength of 532 nm and/or with a power density of about 0.1 to 2 J/cm² are preferred. It is also possible to use an argon laser that emits at a wavelength of 488 nm and 514 nm. A person skilled in the art will be able to choose from various types of lasers in order to tailor the wavelength and power density of the emission to any implanted source substrate 1.

Advantageously, the recycling process 200 comprises a second CMP (chemical-mechanical polishing) substep 220 after the selective electromagnetic irradiation. This substep 220 makes it possible to finish the recycling of the source substrate 1 by treating the surface region 6 once the regions in relief 5 have been removed, in order to obtain a surface topology suited to a new use of the source substrate 1 as a donor substrate of a new thin layer 4. Detachment of this new layer 4 may be carried out after a step of depositing material on the substrate thus obtained, in order to renew the removed material and regenerate the initial thickness of the source substrate. This deposition may be carried out on the recycled surface of the negative (i.e., the surface exposed by the selective electromagnetic irradiation, optionally treated by CMP) or on the opposite side, called the back side. Since the layer 4 is not removed from the back side, the quality of the material is not important and the deposition conditions can be less well controlled. When the contrary is the case, the deposited material will form the new layer 4 and the deposition method used will preferably be MBE (molecular beam epitaxy) or MOCVD (metal organic chemical vapour deposition) or HVPE (hydride vapour phase epitaxy) so as to provide a material with a good crystal quality.

The CMP polishing is a hybrid polishing operation which makes use of the combination of a chemical action and a mechanical force. A fabric, the “pad” is applied with pressure to the rotating surface of the material. A chemical solution, the “slurry”, advantageously containing microparticles in suspension, typically colloids, is applied to the material. The slurry circulates between the surface and the pad and greatly increases the effectiveness of the polishing due to the abrasive nature of the microparticles. Preferably, the CMP polishing of step 220 uses a slurry comprising a colloidal acid solution enriched with diamond particles and/or an oxidizing agent.

The invention furthermore relates to a source substrate 1 recycled by such a process 200, and currently able to be reused in a new process for transferring a layer 4 to a support substrate 3 comprising again steps of:
generating the weakened zone 2 in the recycled source substrate 1 at a depth bounding the thickness of the layer 4;
bringing the recycled source substrate 1 and a support substrate 3 into contact; and
applying a fracturing treatment such as a heat treatment.

It is possible to envisage carrying out several transfer cycles and then recycling a source substrate 1, especially if the source substrate is still thick enough to provide the strength necessary for its manipulation and the compatibility necessary for use with production tools. Moreover, it is possible, as explained above, to reform the removed material on the recycled negative, by epitaxial growth for example, so that the thickness of the source substrate remains constant. Material may also be deposited on the side opposite that used for the removal.

### Example

On a self-supporting GaN source substrate 1 a layer of silicon oxide 500 nm in thickness was deposited. Hydrogen with a dose higher than 1×10¹⁶ atoms/cm² and an energy of 50 to 150 keV, depending on the thickness of the layer 4 to be transferred, was implanted into the GaN through the oxide layer. This led to an average species density of about 1×10²¹ atoms/cm³ near the weakened zone 2 and the material became absorbent at a wavelength longer than or equal to 370 nm. In addition, a layer of 500 nm of silicon oxide was deposited on a sapphire support substrate 3.

The GaN and sapphire substrates were then brought into contact so as to bond them. Their surfaces can possibly be polished just before this contacting step—it is preferable for the RMS surface roughness measured by AFM (atomic force microscope) to be less than 5 ångströms over a 5 micron×5 micron field (this field corresponding to the size of the observed zone).

RMS roughness means the root-mean-square roughness. It is a measurement consisting in measuring the value of the average squared deviation of the roughness. This RMS roughness therefore actually quantifies the average height of the peaks and troughs of the roughness, relative to the average height. This roughness is also monitored by AFM.

Once the substrates had been brought into contact, a heat treatment with a temperature increase to 200 to 700° C. was carried out to strengthen the bond and cause the fracture in the implanted zone. The negative was recovered and the recycling begun.

The ring and the non-transferred zones on the surface of the negative of the GaN source substrate 1 were then removed by irradiation of the entire surface of the source substrate to be recycled at a wavelength of 532 nm with a “doubled YAG” laser, which is an yttrium-aluminium-garnet laser used in pulsed mode with a power density of 0.1 to 2 joules/cm². The unimplanted GaN, the crystal structure of which was not damaged, absorbs at a wavelength shorter than 365 nm. The absorption of the irradiation by the source-substrate negative at 532 nm is therefore selective.

CMP (chemical-mechanical polishing) finished the recycling, a colloidal acid solution provided with an additive such as diamond particles and/or an oxidizing agent can possibly be used. In order to be able to use this substrate in the same way as the initial substrate, it was necessary to polish it until scratches smaller than 15 nm in depth and an RMS roughness lower than 5 åAngströms over a 20 micron×20 micron field (measured by AFM) were obtained.

This substrate could once more be directly used in a process for detaching a layer but could also be used as a seed for epitaxial growth of a new material that restores the thickness of the initial substrate, before being used for the detachment of a new layer.

What is claimed is:

1. A process for recycling a source substrate comprising a surface region and regions in relief on the surface region, with the regions in relief corresponding to residual regions of a layer of the source substrate that were not separated from the rest of the source substrate during a prior removal step, implementing cleavage at a weakened zone formed by damaged material of the source substrate, wherein the surface region corresponds to part of the weakened zone not separated from the rest of the source substrate during the prior removal step, wherein the recycling process comprises applying selective electromagnetic irradiation to the source substrate at a wavelength such that the damaged material of the surface region absorbs the electromagnetic irradiation to facilitate selective removal of the regions in relief.

2. The process according to claim 1, in which the regions in relief correspond to a ring of material from the layer of the source substrate or to other non-transferred zones of material from the layer of the source substrate which zones are distributed randomly on the surface region of the source substrate.

3. The process according to claim 1, in which the selective electromagnetic irradiation is carried out over the entire exposed surface of the source substrate.

4. The process according to claim 1, in which the selective electromagnetic irradiation is controlled by an optical device that detects the regions in relief so that the irradiation is carried out locally on the detected regions in relief.

5. The process according to claim 4, in which the optical device detects the regions in relief via the difference in optical contrast between the damaged material of the weakened zone and the undamaged material of the source substrate.

6. The process according to claim 1, in which the source substrate is a bulk material of SiC or a binary, ternary or quaternary III-N material; or is a composite structure of GaNOS, InGaNOS, SiCOI or SiCopSiC.

7. The process according to claim 1, in which the weakened zone is generated by implanting ionic species into the source substrate.

8. The process according to claim 1, which further comprises conducting chemical-mechanical polishing of the surface region of the source substrate following the selective electromagnetic irradiation of the regions in relief.

9. The process according to claim 8, wherein the chemical-mechanical polishing includes a colloidal acid solution that contains an oxidizing agent, or an additive of abrasive particles, or both.

10. The process according to claim 1, wherein the selective electromagnetic irradiation of the source substrate is carried out by a laser.

11. The process according to claim 10, in which the material of the source substrate is GaN and the laser emits a wavelength longer than or equal to 370 nm.

12. The process according to claim 10, in which the material of the source substrate is SiC and the laser emits a wavelength longer than or equal to 415 nm.

13. The process according to claim 10, in which the laser is a pulsed-mode yttrium-aluminium-garnet laser.

14. The process according to claim 13, in which the laser has a power density of about 0.1 to 2 J/cm².

15. The process according to claim 1, which further comprises epitaxially growing at least one layer of material on a surface of the source substrate.

16. The process according to claim 15, in which the epitaxial growth of material is carried out on the surface to which the selective electromagnetic irradiation is applied.

17. A recycled source substrate prepared by the process of claim 8 in a condition ready to provide an additional layer of material for transfer to a another support substrate.

18. A process for transferring a layer from a recycled source substrate, which comprises:
recycling the polished source substrate obtained by the process of claim 9;
removing a layer from the surface of the recycled source substrate by:
generating a weakened zone in the recycled source substrate at a depth bounding the thickness of the layer; and
applying a fracturing treatment to remove the layer.

19. The process of claim 18, which further comprises, prior to applying the fracturing treatment, bonding the recycled source substrate to a support substrate so that the fracturing treatment transfers the layer to the support substrate.

20. In a process for recycling a source substrate that has been used to supply a layer of surface material by a layer detachment and transfer process and which contains regions in relief relative to the detachment surface which regions include non-transferred zones of damaged material present on the surface of the source substrate, the improvement which comprises providing selective electromagnetic irradiation of the source substrate at a wavelength such that the damaged material of the surface regions in relief absorbs the electromagnetic irradiation to facilitate selective removal of such regions to thus facilitate recycling of the source substrate.

21. The process of claim 20, which further comprises removing the regions in relief from the surface of the source substrate, optionally with polishing, and then recycling the source substrate for removal of a further layer from the surface thereof.
